(19) United States
(12) Patent Application Publication
(10) Pub. No.: US 2024/0183073 A1
(43) Pub. Date: Jun. 6, 2024

(54) METHOD OF MANUFACTURING SILICON CARBIDE SINGLE CRYSTAL AND SILICON CARBIDE SINGLE CRYSTAL

(71) Applicants: DENSO CORPORATION, Kariya-city, Aichi-pref. (JP); TOYOTA JIDOSHA KABUSHIKI KAISHA, Toyota-shi, Aichi-ken (JP); MIRISE Technologies Corporation, Nisshin-shi, Aichi-ken (JP)

(72) Inventors: Soma SAKAKIBARA, Nisshin-shi (JP); Takahiro KANDA, Nisshin-shi (JP)

(21) Appl. No.: 18/482,216

(22) Filed: Oct. 6, 2023

(30) Foreign Application Priority Data
Dec. 6, 2022 (JP) 2022-195054

(51) Int. Cl. C30B 29/36; C01B 32/963; C30B 25/16

(52) U.S. Cl. CPC C30B 29/36; C01B 32/963; C30B 25/165

(57) ABSTRACT

A method of producing a silicon carbide single crystal includes: arranging a seed crystal in a heating container that defines a reaction chamber; and growing a silicon carbide single crystal on a surface of the seed crystal by supplying a supply gas containing a silicon carbide raw material gas while heating the reaction chamber. In the growing of the silicon carbide single crystal, the silicon carbide single crystal is grown by controlling a total pressure of the supply gas, which is an internal pressure of the heating container, to 40 kPa or more while controlling a flow rate of the silicon carbide raw material gas to a target value.

### CROSS REFERENCE TO RELATED APPLICATION

This application is based on Japanese Patent Application No. 2022-195054 filed on Dec. 6, 2022, the disclosure of which is incorporated herein by reference.

### TECHNICAL FIELD

The present disclosure relates to a silicon carbide (hereinafter referred to as SiC) single crystal and a method of manufacturing a SiC single crystal.

### BACKGROUND

In a crystal growth of SiC single crystal, a gas supply method or a sublimation method is used such that a SiC single crystal is grown on a seed crystal. In the gas supply method, a SiC raw material gas is supplied onto the growth surface of the seed crystal from the outside of the reaction container. In the sublimation method, a SiC raw material gas is supplied to a seed crystal by sublimating the SiC raw material in a crucible. An ingot of SiC single crystal grown on the seed crystal is sliced into a wafer shape to form a SiC substrate, which is used for manufacturing a SiC device.

### SUMMARY

According to an aspect of the present disclosure, a method of producing a SiC single crystal includes: arranging a seed crystal in a heating container that forms a reaction chamber; and growing a SiC single crystal on a surface of the seed crystal by supplying a supply gas containing a SiC source gas to the surface of the seed crystal while heating the reaction chamber. The growing of the SiC single crystal includes growing the SiC single crystal by controlling a total pressure of the supply gas, which is an internal pressure of the heating container, to 40 kPa or more while controlling a source flow rate, which is a flow rate of the SiC source gas, to a target flow rate.

### BRIEF DESCRIPTION OF THE DRAWINGS

FIG. 1 is a schematic sectional view illustrating a SiC single crystal manufacturing apparatus according to a first embodiment.

FIG. 2 is a graph showing a change in relationship between a growth amount (mm) and a dislocation density (cm⁻²) of a SiC single crystal.

FIG. 3 is a graph showing an influence of a total pressure (kPa) of a supply gas on the growth rate.

FIG. 4 is a graph showing a change in dislocation density (cm⁻²) with respect to a total pressure (kPa) of a supply gas at a given growth rate.

### DETAILED DESCRIPTION

In a crystal growth of SiC single crystal, a gas supply method or a sublimation method is used such that a SiC single crystal is grown on a seed crystal. In the gas supply method, a SiC raw material gas is supplied onto the growth surface of the seed crystal from the outside of the reaction container. In the sublimation method, a SiC raw material gas is supplied to a seed crystal by sublimating the SiC raw material in a crucible. An ingot of SiC single crystal grown on the seed crystal is sliced into a wafer shape to form a SiC substrate, which is used for manufacturing a SiC device.

The quality of a SiC device is affected by a dislocation density of a SiC substrate. While a long SiC single crystal can be obtained by crystal growth on the surface of the seed crystal, a high quality SiC substrate cannot be obtained if the dislocation density is high. The product yield may be deteriorated in the production of SiC devices, or the SiC single crystal cannot be applied to the production of high-precision devices. The continuation of micropipe from the substrate, to be the seed crystal, to the SiC single crystal is reduced by adjusting the C/Si atomic ratio of the SiC raw material gas.

According to the above method for producing a SiC single crystal, a high quality SiC single crystal can be obtained by reducing the dislocation density. However, in order to increase the production efficiency of the SiC single crystal, it is necessary to increase the growth rate of the SiC single crystal. Although the growth rate of the SiC single crystal can be improved by increasing the flow rate of the raw material gas, in this case, the yield of the raw material is deteriorated, and the crystal quality is deteriorated since the gas core is generated by the excessively supplied raw material. Therefore, improvement is to be achieved both in the growth rate and the high quality of the SiC single crystal.

Such an issue occurs not only in the gas growth method but also in the sublimation method.

The present disclosure provides a method for producing a SiC single crystal capable of achieving both improvement in the growth rate and the high quality. The present disclosure provides a high quality SiC single crystal suitable for manufacturing a SiC device.

According to an aspect of the present disclosure, a method for producing a SiC single crystal includes: arranging a seed crystal in a heating container that forms a reaction chamber; and growing the SiC single crystal on a surface of the seed crystal by supplying a supply gas containing a SiC source gas to the surface of the seed crystal while heating the reaction chamber. The growing of the SiC single crystal includes growing the SiC single crystal by controlling a total pressure of the supply gas, which is an internal pressure of the heating container, to 40 kPa or more while controlling a source flow rate, which is a flow rate of the SiC source gas, to a target flow rate.

As described above, the total pressure of the supply gas is increased, while controlling the raw material flow rate of the SiC raw material gas to be the target flow rate, and the partial pressure of various gases contained in the SiC raw material gas is increased in the vicinity of the crystal surface of the SiC single crystal. Since the partial pressure is improved without increasing the flow rate of the raw material, the deterioration in the yield of the raw material and the crystal quality can be suppressed. Since the growth rate is increased by not lowering the growth surface temperature of the SiC single crystal, the occurrence of insufficient migration on the growth surface of the SiC single crystal is suppressed. Therefore, it is possible to achieve both improvement in the growth rate and the high quality of the SiC single crystal.

According to another aspect of the present disclosure, a SiC single crystal has a Si plane on one surface and a C plane on the other surface. A density of basal plane dislocation is lower on the C plane than on the Si plane, and a density of a dislocation decreases at a reduction rate of 180 cm⁻²/mm or more in a direction from the Si plane to the C plane.

As described above, when the SiC single crystal is grown by increasing the total pressure of the supply gas, while controlling the raw material flow rate of the SiC raw material gas to be the target flow rate, to increase the partial pressure of various gases contained in the SiC raw material gas in the vicinity of the crystal surface of the SiC single crystal, the dislocation density is reduced. Specifically, the dislocation density can be reduced at a reduction rate of 180 cm⁻²/mm or more in the direction from the Si plane to the C plane. Therefore, the quality of the SiC single crystal can be improved to such an extent that the SiC single crystal can be applied to, for example, a high-voltage power device.

Hereinafter, embodiments of the present disclosure will be described with reference to the drawings. In the following embodiments, the same reference numerals are assigned to portions that are the same or equivalent to each other for description.

A SiC single crystal manufacturing apparatus 1 is used for manufacturing a SiC single crystal according to an embodiment.

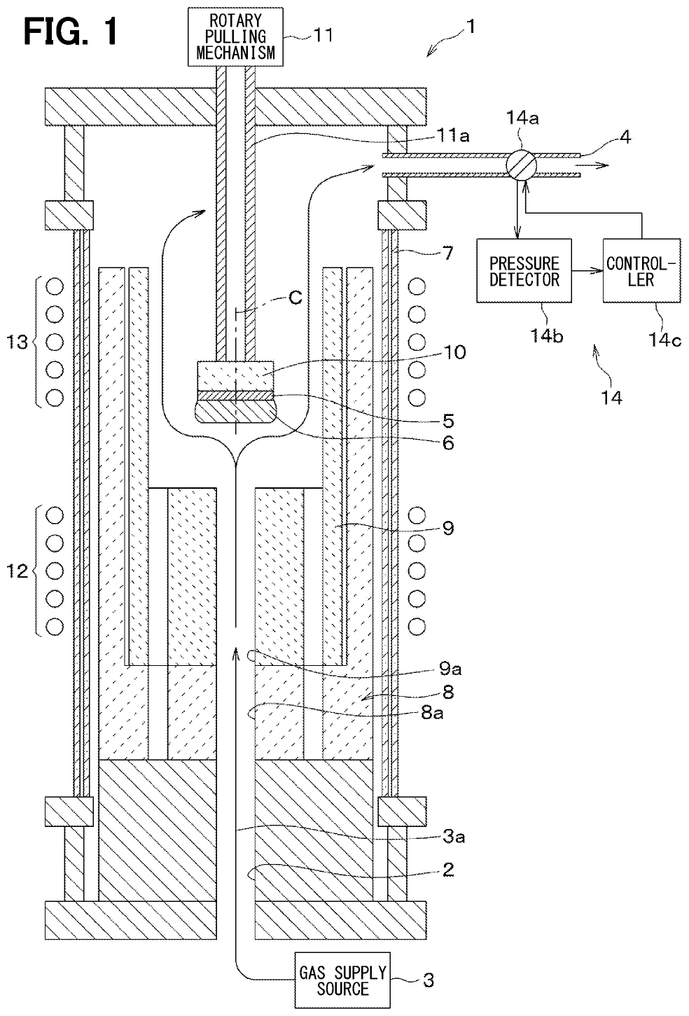

The SiC single crystal manufacturing apparatus 1 shown in FIG. 1 is used for manufacturing a SiC single crystal ingot by elongated growth based on a gas supply method. The SiC single crystal manufacturing apparatus 1 is installed such that the up-down direction of FIG. 1 corresponds to the vertical direction.

Specifically, the SiC single crystal manufacturing apparatus 1 causes a supply gas 3a containing a SiC raw material gas from a gas supply source 3 to flow in through a gas supply port 2, and causes an unreacted gas to be exhausted through a gas exhaust port 4, thereby growing a SiC single crystal 6 on a seed crystal 5 formed of a SiC single crystal substrate.

The SiC single crystal manufacturing apparatus 1 includes the gas supply source 3, a vacuum chamber 7, a heat insulating member 8, a heating container 9, a pedestal 10, a rotary pulling mechanism 11, a first heating device 12, a second heating device 13 and a pressure adjustment unit 14.

The gas supply source 3 supplies the supply gas 3a including at least a mixed gas of a SiC raw material gas containing Si and C, for example, a silane-based gas such as silane (SiH₄) and a hydrocarbon-based gas such as propane (C₃H₈), from the cylindrical gas supply port 2. The gas supply source 3 of a gas supply mechanism supplies the SiC raw material gas from the lower side of the seed crystal 5 from the outside of the heating container 9.

The gas supply source 3 may supply at least the SiC source gas as the supply gas 3a, but it is also possible to increase the flow rate by diluting the SiC source gas or adjust the concentration of source gas by supplying the carrier gas together. The gas supply source 3 can supply an etching gas instead of or in addition to the carrier gas. When the gas supply source 3 supplies the etching gas, it is possible to restrict adhesion of by-products to locations where adhesion is not desired, in addition to adjusting the flow rate and the concentration of the SiC raw material gas. As the carrier gas, an inert gas such as He, Ar, and the like can be used. As the etching gas, H₂, HCl, and the like can be used. Furthermore, when introducing a dopant into the SiC single crystal 6 to be grown, an N source that becomes an n-type dopant such as N₂ (nitrogen) can also be introduced. Not only an n-type dopant such as an N source, but also an Al (aluminum) source and a B (boron) source, which are p-type dopants, can be introduced.

The supply gas 3a is supplied from the gas supply source 3 through the gas supply port 2 at a lower position of the SiC single crystal manufacturing apparatus 1. However, the SiC source gas, the carrier gas, and the etching gas may be supplied not only through one gas supply port 2 but also through separate supply ports.

The vacuum chamber 7 is made of quartz glass or the like, and has a tube shape providing a hollow portion. In the present embodiment, the vacuum chamber 7 has a cylindrical shape, and the supply gas 3a can be introduced and exhausted. The vacuum chamber 7 houses other components of the SiC single crystal manufacturing apparatus 1, and can be decompressed by vacuuming the internal space. The gas supply port 2 for the supply gas 3a is disposed at a bottom of the vacuum chamber 7, and the gas exhaust port 4 is disposed at an upper position of a side wall of the vacuum chamber 7.

The heat insulating member 8 has a tube shape providing a hollow portion, in the present embodiment, a bottomed cylindrical shape, and is disposed coaxially with the vacuum chamber 7. The heat insulating member 8 has a cylindrical shape with a diameter smaller than a diameter of the vacuum chamber 7, and is disposed inside the vacuum chamber 7, thereby inhibiting a heat transfer from a space inside the heat insulating member 8 to the vacuum chamber 7. The heat insulating member 8 is made of, for example, graphite alone or graphite whose surface is coated with a high-melting point metal carbide such as TaC (tantalum carbide) or NbC (niobium carbide), and is hardly subjected to thermal etching.

The heat insulating member 8 has an introduction hole 8a at a center of the bottom of the heat insulating member 8. The introduction hole 8a penetrates through the bottom of the heat insulating member 8 and is connected to the gas supply port 2 so that the supply gas 3a introduced from the gas supply port 2 is introduced into the heat insulating member 8 through the introduction hole 8a.

The heating container 9 is a crucible that constitutes a reaction chamber for growing the SiC single crystal 6 by thermally decomposing the SiC raw material gas, and is configured in a cylindrical shape having a hollow portion, or in a bottomed cylindrical shape in the present embodiment. The hollow portion of the heating container 9 serves as a growth space for growing the SiC single crystal 6 on the surface of the seed crystal 5. The heating container 9 is made of, for example, graphite alone or graphite whose surface is coated with a high-melting point metal carbide such as TaC or NbC, and is hardly subjected to thermal etching. The heating container 9 is disposed to surround the pedestal 10. The heating container 9 decomposes the SiC raw material gas by the time the supply gas 3a from the gas supply port 2 is led to the seed crystal 5.

The heating container 9 has an introduction hole 9a at a center of the bottom of the heating container 9, and is connected to the gas supply port 2 and the introduction hole 8a. The supply gas 3a introduced from the gas supply port 2 and the introduction hole 8a is guided into the heating container 9 through the introduction hole 9a.

The pedestal 10 is a member on which the seed crystal 5 is disposed. One surface of the pedestal 10 on which the seed crystal 5 is placed has a shape corresponding to the shape of the seed crystal 5. The pedestal 10 is disposed so that the central axis of the pedestal 10 is coaxial with the central axis of the heating container 9 and the central axis of a shaft 11a of the rotary pulling mechanism 11, which will be described later. In the present embodiment, the pedestal 10 is formed of a columnar member having the same diameter as that of the seed crystal 5, so that one surface on which the seed crystal 5 is installed has a circular shape, and the center line C of the circular shape is coaxial with the central axis of the heating container 9. The pedestal 10 is made of, for example, graphite alone or graphite whose surface is coated with a high-melting point metal carbide such as TaC or NbC, and is hardly subjected to thermal etching.

The seed crystal 5 is attached to the one surface of the pedestal 10 opposing the gas supply port 2, and the SiC single crystal 6 is grown on the surface of the seed crystal 5. Further, the pedestal 10 is connected to the shaft 11a on a surface opposite to the seed crystal 5. The pedestal 10 is rotated with the rotation of the shaft 11a, and can be pulled upward when the shaft 11a is pulled up.

The rotary pulling mechanism 11 rotates and pulls up the pedestal 10 through the shaft 11a formed of a pipe member or the like. In the present embodiment, the shaft 11a is formed in a straight line extending up and down, and one end of the shaft 11a is connected to the surface of the pedestal 10 opposite to the seed crystal 5. The other end of the shaft 11a is connected to a main body of the rotary pulling mechanism 11. The shaft 11a is also made of, for example, graphite alone or graphite whose surface is coated with a high-melting point metal carbide such as TaC or NbC, and is hardly subjected to thermal etching. With the above configuration, the pedestal 10, the seed crystal 5, and the SiC single crystal 6 can be rotated and pulled up, so that a growth plane of the SiC single crystal 6 can have a desired temperature distribution, and a temperature of the growth surface can be adjusted to a temperature suitable for growth along with the growth of the SiC single crystal 6.

Each of the first heating device 12 and the second heating device 13 includes a heating coil such as an induction heating coil and a direct heating coil, and is arranged to surround the vacuum chamber 7 to heat the heating container 9. In the present embodiment, each of the first heating device 12 and the second heating device 13 includes an induction heating coil. The first heating device 12 and the second heating device 13 are configured to be capable of independently controlling the temperature of a target location. The first heating device 12 is disposed at a position corresponding to the heating container 9, and the second heating device 13 is disposed at a position corresponding to the pedestal 10. Therefore, the temperature of the lower portion of the heating container 9 can be controlled by the first heating device 12 to heat and decompose the SiC raw material gas. The temperature around the pedestal 10, the seed crystal 5, and the SiC single crystal 6 can be controlled to a temperature suitable for the growth of the SiC single crystal 6 by the second heating device 13. In the present embodiment, a heating device includes the first heating device 12 and the second heating device 13. However, the heating device may include only the first heating device 12, or the locations of these devices may be changed as appropriate.

The pressure adjustment unit 14 is a mechanism that adjusts the internal pressure of the SiC single crystal manufacturing apparatus 1, that is, the gas pressure in the growth space of the SiC single crystal 6. The internal pressure of the SiC single crystal manufacturing apparatus 1 is the gas pressure in the vacuum chamber 7, and it can be considered that the pressure is substantially the same at any place in the vacuum chamber 7. The pressure adjustment unit 14 adjusts the gas pressure in the growth space by adjusting the gas pressure in the vacuum chamber 7. Specifically, the pressure adjustment unit 14 is disposed at the gas exhaust port 4, and includes a pressure adjustment valve 14a, a pressure detector 14b, and a controller 14c.

The pressure adjustment valve 14a is configured by an electromagnetic valve or the like, and the opening degree thereof is controlled by the controller 14c, thereby adjusting the flow rate of the gas discharged through the gas exhaust port 4 to adjust the internal pressure of the SiC single crystal manufacturing apparatus 1. The pressure detector 14b detects the internal pressure of the SiC single crystal manufacturing apparatus 1 through the gas exhaust port 4, and inputs a detection signal corresponding to the internal pressure to the controller 14c. The controller 14c is configured by a microcomputer including a CPU, a ROM, a RAM, an I/O, and the like. The controller 14c controls the internal pressure of the SiC single crystal manufacturing apparatus 1 to be the target pressure by outputting the control signal of the pressure adjustment valve 14a based on the detection signal of the pressure detector 14b.

The SiC single crystal manufacturing apparatus 1 according to the present embodiment is configured as described above. Subsequently, a manufacturing method of the SiC single crystal 6 using the SiC single crystal manufacturing apparatus 1 according to the present embodiment will be described.

As the seed crystal 5, an off-substrate having a Si plane on one surface and a Ci plane on the other surface is prepared. Specifically, the off substrate is made of 4H—SiC having a predetermined off angle such as 4 degrees or 8 degrees with respect to a C plane, more specifically, a (000-1) C plane. The seed crystal 5 is attached to the pedestal 10 in such a manner that the Si plane faces the pedestal 10 and the C plane opposite from the pedestal 10 is to be a growth surface of the SiC single crystal 6.

Subsequently, the pedestal 10 and the seed crystal 5 are disposed in the heating container 9. Then, the heating container 9 is heated by controlling the first heating device 12 and the second heating device 13 to obtain a desired temperature distribution. In other words, the temperature distribution is controlled such that the SiC raw material gas contained in the supply gas 3a is heated and decomposed to be supplied to the surface of the seed crystal 5, and the SiC raw material gas is recrystallized on the surface of the seed crystal 5, while a sublimation rate is higher than a recrystallization rate in the heating container 9. Specifically, the temperature in the heating container 9 is set to a high temperature of 2000° C. or higher, preferably an environment in which at least a part of the temperature is 2500° C. or higher. For example, the temperature of the bottom of the heating container 9 is set to about 2800±100° C., and the temperature of the surface of the seed crystal 5 is set to about 2500±100° C.

Further, the supply gas 3a containing the SiC raw material gas is introduced through the gas supply port 2 while the internal pressure of the SiC single crystal manufacturing apparatus 1, that is, the vacuum chamber 7 is set to a desired target pressure. By controlling the internal pressure of the SiC single crystal manufacturing apparatus 1 to be the target pressure, it is possible to control the partial pressure of the silane-based gas such as silane or the hydrocarbon-based gas such as propane to be adjusted to the temperature. In addition, if necessary, a carrier gas of an inert gas such as He or Ar or an etching gas such as H₂ or HCl is introduced, and the flow rate and the concentration of the raw material gas are adjusted so that by-products are less likely to be generated. Accordingly, the supply gas 3a flows as shown by the arrows in FIG. 1 and is supplied to the seed crystal 5, and the SiC single crystal 6 is grown on the surface of the seed crystal 5 by the source gas included in the supply gas 3a.

Then, the rotary pulling mechanism 11 pulls up the pedestal 10, the seed crystal 5 and the SiC single crystal 6 in accordance with the growth rate of the SiC single crystal 6 while rotating them through the shaft 11a. As a result, a height of the growth surface of the SiC single crystal 6 is kept substantially constant, and the temperature distribution of the growth surface temperature can be controlled with high controllability.

The inventors have intensively studied to achieve improvement both in the growth rate and the high quality when growing a SiC single crystal, and have found a method of controlling the internal pressure of the SiC single crystal manufacturing apparatus 1, that is, the pressure of the supply gas 3a. Hereinafter, this process will be described. In the following description, the total pressure of the supply gas 3a including all the gases is referred to as total pressure Pₜₒₜₐₗ. Although the total pressure Pₜₒₜₐₗ is the internal pressure of the SiC single crystal manufacturing apparatus 1, since the total pressure Pₜₒₜₐₗ is substantially the same at any place inside the SiC single crystal manufacturing apparatus 1, the total pressure Pₜₒₜₐₗ corresponds to the pressure applied to the growth surface of the SiC single crystal 6, that is, the internal pressure of the heating container 9 constituting the reaction chamber.

The SiC single crystal manufacturing apparatus 1 described in the present embodiment manufactures the SiC single crystal 6 by a high temperature chemical vapor deposition (HTCVD) method based on a gas supply method. The HTCVD method is used for manufacturing the SiC single crystal 6 by vacuum vapor deposition at a high temperature of 2000° C. or higher using a high-purity SiC raw material gas. The crystal growth rate and the like in the HTCVD method are expressed by the following mathematical formulas.

$$G R ∝ ( {P}_{S i H 4} - {P}_{e} ) \qquad ( Formula 1 )$$

$${P}_{e} = {A}_{e}^{- \frac{L}{R T}} \qquad ( Formula 2 )$$

$${P}_{S i H 4} = {P}_{total} \times \frac{{f}_{S i H 4}}{{f}_{total}} \qquad ( Formula 3 )$$

$$GR ∝ ( {P}_{total} \times \frac{{f}_{S i H 4}}{{f}_{total}} ) - {A}_{e}^{- \frac{L}{R T}} \qquad ( Formula 4 )$$

In Formulas 1 to 4, GR is the growth rate of the SiC single crystal 6, P_{SiH4} is the partial pressure of the silane serving as the Si raw material gas, and F_{SiH4} is the raw material flow rate of the silane. In addition, A is a constant, L is a reaction heat, R is a gas constant, T is a growth surface temperature of the SiC single crystal 6, and Pe is a saturated vapor pressure. Although the raw material flow rate f_{C3H8} of propane to be the C raw material gas is not shown in the mathematical formulas, the target flow rate is ⅓, which is the ratio of the raw material to the raw material flow rate f_{SiH4} of silane. The same applies to the partial pressure P_{C3H8} of propane. The target flow rate is ⅓, which is the ratio of the raw material relative to the partial pressure P_{SiH4} of the silane. In other words, the partial pressure P_{C3H8} is set such that the ratio of C/Si, which is the ratio of C to Si contained in silane and propane, is 1.

As shown in Formula 4, in order to increase the growth rate GR, the total pressure Pₜₒₜₐₗ may be increased, or the partial pressures P_{SiH4}, P_{C3H8} may be increased by increasing the raw material flow rate f_{SiH4}, f_{C3H8}. The growth rate GR can be increased by lowering the growth surface temperature T of the SiC single crystal 6.

However, as a method of increasing the growth rate GR, when the raw material flow rate f_{SiH4}, f_{C3H8} is increased to improve the partial pressure P_{SiH4}, P_{C3H8}, the yield of the raw material is deteriorated, and the gas core is generated by the excessively supplied raw material such that the crystal quality is deteriorated. On the other hand, it is confirmed that when the growth surface temperature T is lowered to increase the growth rate GR, the quality is deteriorated due to insufficient migration on the growth surface of the SiC single crystal 6. Therefore, in the method of increasing the raw material flow rate f_{SiH4}, f_{C3H8} to improve the partial pressure P_{SiH4}, P_{C3H8} and the method of decreasing the growth surface temperature T, the crystal quality cannot be secured while the growth rate GR is increased. Thus, it is difficult to achieve improvement both in the growth rate of the SiC single crystal 6 and the high quality.

As a result of intensive studies by the present inventors, it has been found that both can be achieved by increasing the total pressure Pₜₒₜₐₗ to increase the partial pressures P_{SiH4} and P_{C3H8} in the vicinity of the crystal surface of the SiC single crystal 6 while controlling the raw material flow rate f_{SiH4}, f_{C3H8} to be constant at the target flow rate.

Since the raw material flow rate f_{SiH4}, f_{C3H8} is controlled to be the target flow rate, insufficient migration on the crystal surface of the SiC single crystal 6 is suppressed, such that the quality of the SiC single crystal 6 can be improved. Since the partial pressures P_{SiH4} and P_{C3H8} in the vicinity of the crystal surface of the SiC single crystal 6 are increased by increasing the total pressure Pₜₒₜₐₗ, the growth rate GR of the SiC single crystal 6 can be improved. This makes it possible to achieve both improvement in the growth rate of the SiC single crystal 6 and the high quality.

The applicable total pressure Pₜₒₜₐₗ is set to 40 kPa or more, preferably 50 kPa or more, because if it is too low, the efficiency decreases since it is necessary to increase the raw material flow rates f_{SiH4} and f_{C3H8}. In addition, the higher the total pressure Pₜₒₜₐₗ is, the higher the growth rate of the SiC single crystal 6 is. Thus, the efficiency can be raised. However, in order to suppress gas leakage from the SiC single crystal manufacturing apparatus 1, it is preferable to set the total pressure Pₜₒₜₐₗ to a reduced pressure atmosphere lower than the atmospheric pressure. However, this is not limited thereto while a dedicated pressure-resistant and heat-resistant container is prepared.

Hereinafter, the reason why the improvement in the growth rate of the SiC single crystal 6 and the high quality can be achieved at the same time will be described with reference to the experimental results.

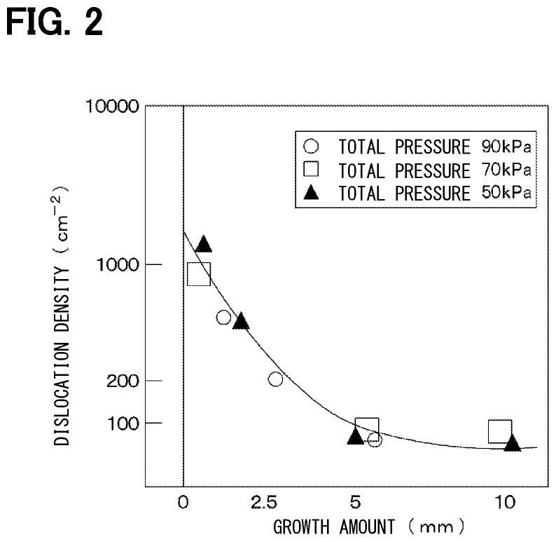

First, the change in the relationship between the growth amount (mm) of the SiC single crystal 6 and the dislocation density (cm⁻²) is examined by changing the total pressure Pₜₒₜₐₗ. FIG. 2 shows the results. As shown in FIG. 2, the total pressure Pₜₒₜₐₗ is set to three different values of 50 kPa, 70 kPa, and 90 kPa. Here, experiments are performed by setting the raw material flow rate f_{SiH4}, f_{C3H8} to constant target flow rate and setting the flow rate ratio thereof to be constant. Here, as an example, the raw material flow rate f_{SiH4} and the raw material flow rate f_{C3H8} are set to values corresponding to the raw material ratio of Si:C. In addition, a carrier gas or an etching gas is appropriately introduced, and the total pressure Pₜₒₜₐₗ is adjusted to a constant pressure by the pressure adjustment unit 14. In addition, the partial pressure P_{SiH4} of silane is set to 3 kPa to 30 kPa, and the partial pressure P_{C3H8} of propane is set such that C/Si becomes 1 corresponding to the partial pressure P_{SiH4}. Then, the growth amount is measured, when the SiC single crystal 6 is grown under each pressure. The growth amount is a distance in the growth direction from the surface of the seed crystal 5, that is, a distance along the center line C in FIG. 1. Further, the dislocation density is measured at the position of the growth amount. The dislocation density is measured by cutting the SiC single crystal 6 at a location of a growth amount to be measured, etching the cut surface with a KOH melt for 1 hour, and observing a defect as a pit shape. The dislocation density represents the number of different dislocations contained per unit area cm². The dislocations include dislocations such as micropipes and basal plane dislocations (BPD). The dislocation can be measured by an optical microscope or the like regardless of the size. It is not necessary to measure the dislocation density over the entire surface of the cut SiC single crystal 6, and the dislocation density at the growth amount to be measured can be obtained by measuring the dislocation density at several places in a predetermined range.

As shown in FIG. 2, in the experiments, the dislocation density is about 1000 cm⁻² in the initial stage of growth of the SiC single crystal 6, that is, in the vicinity of the growth amount of 0 mm. However, in the vicinity of the growth amount of 5 mm, the dislocation density is reduced to 100 cm⁻² or less. In other words, the dislocation density is reduced to be 1/10 or less, by one digit or more. In terms of the reduction rate of the dislocation density, since the dislocation density is reduced from 1000 cm⁻² to 100 cm⁻² or less with a growth amount of 5 mm, the reduction rate is 180 cm⁻²/mm or more. Further, when the growth amount exceeds 10 mm, the dislocation density could be maintained at 100 cm⁻² or less, since the rate of decrease in the dislocation density is reduced while the dislocation density gradually decreases.

A SiC substrate is cut out of the SiC single crystal 6 to manufacture a device. Although the required dislocation density varies depending on the specifications of the applied device, a high-quality SiC substrate having a dislocation density of 100 cm⁻² or less is applicable to a high-voltage power device such as a MOSFET. In applications other than high-voltage power devices, it is sufficiently possible to apply a SiC substrate having a dislocation density of 200 cm⁻² or less. When the growth amount of the SiC single crystal 6 is 2.5 mm or more, the dislocation density can be 200 cm⁻² or less. Thus, the quality can be improved to the extent that the SiC single crystal 6 can be applied to applications other than high-voltage power devices. In addition, it can be seen that in a place where the growth amount of the SiC single crystal 6 is 5 mm or more, the quality can be improved to be applicable to a high voltage power device having a dislocation density of 100 cm⁻² or less.

As shown in FIG. 2, regardless of the total pressure Pₜₒₜₐₗ, the change in the dislocation density with respect to the growth amount has the same tendency, and the dislocation density decreases as the growth amount increases. This means that a change in the total pressure Pₜₒₜₐₗ does not affect the dislocation density. When the total pressure Pₜₒₜₐₗ is varied, the dislocation density can be reduced according to the growth amount. Therefore, even while the total pressure Pₜₒₜₐₗ is increased and the partial pressures P_{SiH4} and P_{C3H8} in the vicinity of the crystal surface of the SiC single crystal 6 are increased, the dislocation density is not increased, such that it is possible to improve the quality of the SiC single crystal 6.

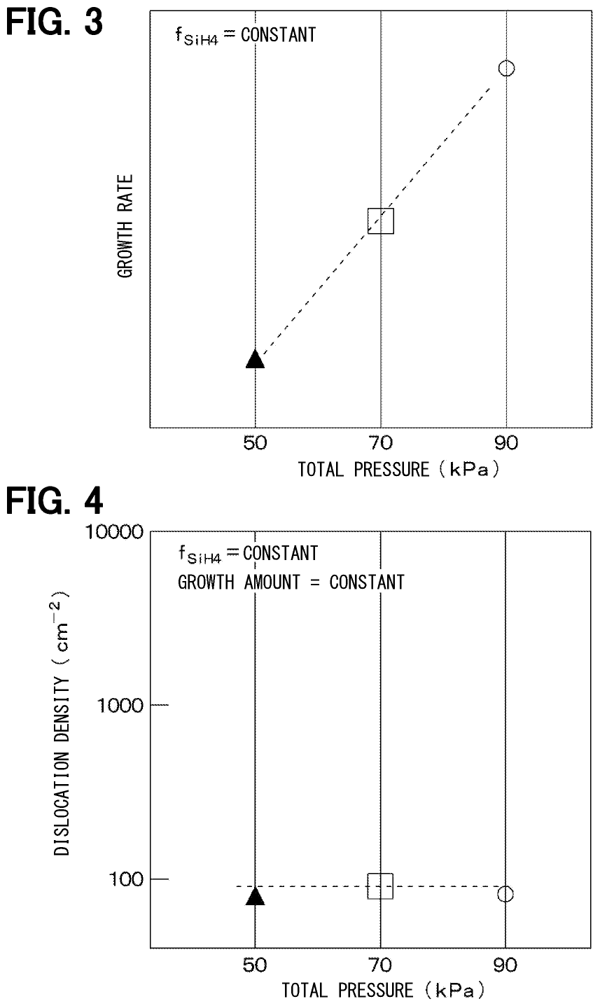

Next, the influence of the total pressure Pₜₒₜₐₗ on the growth rate GR is examined. FIG. 3 shows the results. In the experiments, the conditions of the raw material flow rates f_{SiH4} and f_{C3H8}, the carrier gas, and the etching gas are the same as those in the experiments of FIG. 2, and the total pressure Pₜₒₜₐₗ is set to three different values of 50 kPa, 70 kPa, and 90 kPa.

As shown in FIG. 3, the growth rate GR of the SiC single crystal 6 depends on the total pressure Pₜₒₜₐₗ. The growth rate GR increases as the total pressure Pₜₒₜₐₗ increases. Therefore, it can be seen that the growth rate GR can be increased by increasing the total pressure Pₜₒₜₐₗ.

Further, a change in the dislocation density with respect to the total pressure Pₜₒₜₐₗ at a constant growth amount is examined. FIG. 4 shows the results. Also in the experiments, the conditions of the raw material flow rates f_{SiH4} and f_{C3H8}, the carrier gas, and the etching gas are the same as those in the experiments of FIG. 2, and the total pressure Pₜₒₜₐₗ is set to three different values of 50 kPa, 70 kPa, and 90 kPa.

As shown in FIG. 4, the dislocation density with respect to the growth rate GR at a certain growth amount does not change when the total pressure Pₜₒₜₐₗ is changed. Specifically, the dislocation density is 100 cm⁻² or less in all cases where the total pressure Pₜₒₜₐₗ is 50 kPa, 70 kPa, or 90 kPa. This means that when the raw material flow rates f_{SiH4} and f_{C3H8} are constant, the dislocation density with respect to the growth rate GR at a certain growth amount becomes constant. That is, if the raw material flow rates f_{SiH4} and f_{C3H8} are constant, it is possible to restrict the quality of the SiC single crystal 6 from deteriorating even if the total pressure Pₜₒₜₐₗ is different. Thus, it is possible to improve the quality of the SiC single crystal 6 to such an extent that the SiC single crystal 6 can be applied to a high-voltage power device.

As described above, in the present embodiment, the partial pressures P_{SiH4} and P_{C3H8} in the vicinity of the crystal surface of the SiC single crystal 6 are increased by increasing the total pressure Pₜₒₜₐₗ to 40 kPa or more while controlling the raw material flow rates f_{SiH4} and f_{C3H8} to be constant at the target flow rates.

As described above, since the partial pressures P_{SiH4} and P_{C3H8} are increased without increasing the raw material flow rates f_{SiH4} and f_{C3H8}, the deterioration in the yield of the raw material and the crystal quality can be suppressed. The gas core is not generated by the excessively supplied raw material. In addition, since the growth surface temperature T is not lowered to increase the growth rate GR, the occurrence of insufficient migration on the growth surface of the SiC single crystal 6 is suppressed. Therefore, it is possible to achieve improvement in both of the growth rate GR of the SiC single crystal 6 and the high quality.

The seed crystal 5 used for the growth of the SiC single crystal 6 has the Si plane facing the pedestal 10 on the one surface, and the C plane, which is the growth plane of the SiC single crystal 6, on the other surface. However, in the obtained SiC single crystal 6, the dislocation density is lower in the C plane than in the Si plane. That is, the SiC single crystal 6 grown from the surface of the seed crystal 5 has the BPD density lower than the BPD density of the seed crystal 5 at the initial growth position of the SiC single crystal 6 close to the seed crystal 5, and then the dislocation density does not increase along the growth direction of the SiC single crystal 6, that is, the direction away from the seed crystal 5. Then, as the growth of the SiC single crystal 6 progresses, the dislocation density decreases, and preferably, the SiC single crystal 6 can be grown without increasing the dislocation density thereafter. With such a configuration, the SiC single crystal 6 can be made more suitable for manufacturing a SiC device with higher quality with the progress of growth. Further, when the SiC substrate is manufactured by slicing the SiC single crystal 6, it is possible to obtain a SiC substrate having a low dislocation density and good device characteristics.

Specifically, while controlling the raw material flow rates f_{SiH4} and f_{C3H8} to be constant at the target flow rates, the SiC single crystal 6 is manufactured at a total pressure Pₜₒₜₐₗ of 40 kPa or more, preferably 50 kPa or more, and the SiC single crystal 6 is sliced to manufacture the SiC substrate. When the SiC substrate produced in this manner is examined, the carrier lifetime is 5 ns or less, and the concentration of carbon vacancies (Vc), which means C (carbon) vacancies, was 1×10¹⁵ cm⁻³ or more. The SiC substrate has high quality in which the dislocation density is suppressed. When the SiC single crystal 6 is grown by the gas supply method, the concentration of the carbon vacancies Vc tends to be higher than that by the sublimation method. However, according to the manufacturing method of the present embodiment, the concentration of the carbon vacancies Vc can be further increased. Since the carbon vacancies Vc are the recombination center with the hole, it is possible to suppress the expansion of 1SSF (Single-Shockley stacking fault), which is the cause of the forward degradation of the diode due to the high concentration of the carbon vacancies Vc.

In addition, the total concentration of metal impurities mixed as impurities that are not intended dopants is 2×10¹⁵ atm/cm³ or less, and a SiC substrate having good device characteristics is obtained. More specifically, Al (aluminum) has concentration of 1×10¹¹ atm/cm³ or less, B (boron) has concentration of 1×10¹¹ atm/cm³ or less, Ti (titanium) has concentration of 7×10¹² atm/cm³ or less, and V (vanadium) has concentration of 5×10¹² atm/cm³ or less. The metal impurity concentration is a low level at which good device characteristics are obtained when the SiC wafer is used for forming a semiconductor device.

Further, in order to dope N as an n-type impurity as a dopant, N₂ is introduced into the supply gas 3a to manufacture the SiC single crystal 6, and the SiC single crystal 6 is sliced to manufacture the SiC substrate. As a result, a SiC substrate having an n-type impurity concentration of 5 to 9×10¹⁸ atm/cm³ or more is obtained. Such a high-concentration SiC substrate can be used, for example, as a portion constituting a drain region when an n-type MOSFET or the like is manufactured as a high-voltage power device. In addition, since the SiC substrate is a high-quality SiC substrate having a low dislocation density, the dislocation density of the drift layer can be reduced when the drift layer is epitaxially grown on the surface of the SiC substrate. Therefore, BPD is suppressed from expanding to 1SSF, and it is possible to provide a high-voltage power device capable of suppressing an increase in on-resistance.

Similarly, in order to dope Al as a p-type impurity as a dopant, TMA (trimethylaluminum) is introduced into the supply gas 3a to manufacture a SiC single crystal 6, and the SiC single crystal 6 is sliced to manufacture a SiC substrate. As a result, a SiC substrate having a p-type impurity concentration of 1×10¹¹ atm/cm³ or less is obtained. Such a high-concentration SiC substrate can be used as a portion constituting a collector region when an IGBT or the like is manufactured as a high-voltage power device. In addition, since the SiC substrate is a high-quality SiC substrate having a low dislocation density, even when a drift layer is epitaxially grown on the surface of the SiC substrate, the dislocation density of the drift layer can be reduced. Thus, the same effects as in the case of doping with an n-type impurity can be obtained.

### Other Embodiments

Although the present disclosure is described with reference to the embodiments described above, the present disclosure is not limited to such embodiments but may include various changes and modifications which are within equivalent ranges. In addition, various combinations and modes, and other combinations and modes including only one element, more elements, or less elements are also within the scope and idea of the present disclosure.

That is, the SiC single crystal manufacturing apparatus 1 may have any structure while the partial pressure P_{SiH4} near the crystal surface of the SiC single crystal 6 can be increased by increasing the total pressure Pₜₒₜₐₗ while controlling the raw material flow rates f_{SiH4} and f_{C3H8} to be the target flow rates. For example, the SiC single crystal manufacturing apparatus 1 shown in FIG. 1 is merely an example, and the configurations such as the structures of the heating container 9 and the heat insulating member 8 may be partially different. As a mechanism for controlling the total pressure Pₜₒₜₐₗ of the SiC single crystal manufacturing apparatus 1, the pressure adjustment unit 14 is provided at the gas exhaust port 4 shown in FIG. 1. However, it is not limited, and the pressure adjustment unit 14 may be provided at a location different from the gas exhaust port 4.

In addition, “controlling the raw material flow rates f_{SiH4} and f_{C3H8} to the target flow rate” or “controlling the raw material flow rates f_{SiH4} and f_{C3H8} to be constant at the target flow rate” is not limited to a case where there is no change from the target flow rate, and includes a case where the raw material flow rates f_{SiH4} and f_{C3H8} are adjusted to the target flow rate by various types of control such as feedback control. Similarly, the total pressure Pₜₒₜₐₗ may be increased while the total pressure Pₜₒₜₐₗ can be controlled to reach the target pressure of 40 kPa or more, and is not limited to the case where there is no change from the target pressure, but also includes the case where the total pressure Pₜₒₜₐₗ is adjusted to reach the target pressure by various types of control such as feedback control.

In FIG. 1, the ingot-shaped material formed on the surface of the seed crystal 5 is illustrated as the SiC single crystal 6, but the SiC single crystal 6 may be either an ingot or a wafer-shaped SiC substrate obtained by cutting out the ingot.

In the above embodiment, the SiC single crystal growth apparatus and the manufacturing method has the up-flow type in which the supply gas 3a containing the SiC raw material gas is supplied to the seed crystal 5 from the lower side. However, the configuration of the gas supply mechanism is not limited thereto, and may be a side flow system or a down flow system. Further, in the above embodiment, the gas supply method is applied as the SiC single crystal manufacturing apparatus 1, but a sublimation method may be applied.

Further, in the above embodiment, the SiC single crystal 6 is n-doped or p-doped, but it is possible to limit the impurity doping to make the SiC single crystal 6 semi-insulating. In this case, it is sufficient not to introduce N₂ or TMA as a doping source of an n-type impurity such as N or a p-type impurity such as Al. In this case, it is possible to manufacture the semi-insulating SiC single crystal 6 in which a metal impurity contains B having a concentration of 1×10¹¹ atm/cm³ or less, Ti having a concentration of 7×10¹² atm/cm³ or less, and V having a concentration of 5×10¹² atm/cm³ or less.

Further, in the above embodiment, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number.

It should be noted that if the orientation of the crystal is to be indicated, a bar (−) should originally be attached above a desired number, but since there are restrictions on the representation based on the electronic application, the bar is attached before the desired number in the present specification.

The controller and the method thereof described in the present disclosure may be implemented by a special purpose computer including a processor programmed to execute one or more functions by executing a computer program and a memory. Alternatively, the controller and the method described in the present disclosure may be implemented by a special purpose computer including a processor with one or more dedicated hardware logic circuits. Alternatively, the controller and the method described in the present disclosure may be implemented by one or more special purpose computer, which is configured as a combination of a processor and a memory, which are programmed to perform one or more functions, and a processor which is configured with one or more hardware logic circuits. A computer program may be stored in a computer-readable non-transitory tangible recording medium as an instruction executed by a computer.

What is claimed is:

1. A method of producing a silicon carbide single crystal comprising:
arranging a seed crystal in a heating container having a hollow shape forming a reaction chamber; and
growing a silicon carbide single crystal on a surface of the seed crystal by supplying a supply gas containing a silicon carbide raw material gas while heating the reaction chamber, wherein
the growing of the silicon carbide single crystal includes growing the silicon carbide single crystal by controlling a total pressure of the supply gas, which is an internal pressure of the heating container, to 40 kPa or more while controlling a flow rate of the silicon carbide raw material gas to a target flow rate.

2. The method according to claim 1, wherein the growing of the silicon carbide single crystal includes forming an ingot of the silicon carbide single crystal and decreasing a dislocation density in the silicon carbide single crystal in a growth direction of the silicon carbide single crystal.

3. The method according to claim 1, wherein the total pressure is controlled to 50 kPa or more in the growing of the silicon carbide single crystal.

4. The method according to claim 1, wherein the total pressure is controlled to be equal to or lower than an atmospheric pressure in the growing of the silicon carbide single crystal.

5. The method according to claim 1, wherein
silane and propane are used as the silicon carbide raw material gas in the growing of the silicon carbide single crystal,
a partial pressure of the silane is set in a range between 3 kPa and 30 kPa, and
a partial pressure of the propane is set such that C/Si, which is a ratio of C to Si contained in the silane and the propane, is 1.

6. A silicon carbide single crystal comprising: a Si plane on one surface and a C plane on the other surface, wherein
a density of a basal plane dislocation is lower on the C plane than on the Si plane, and
a density of dislocation decreases at a reduction rate of 180 cm⁻²/mm or more in a direction from the Si plane to the C plane.

7. The silicon carbide single crystal according to claim 6, wherein the density of dislocation is 100 cm⁻² or less.

8. The silicon carbide single crystal according to claim 6, comprising: a metal impurity containing B having a concentration of 1×10¹¹ atm/cm³ or less, Ti having a concentration of 7×10¹² atm/cm³ or less, and V having a concentration of 5×10¹² atm/cm³ or less.

9. The silicon carbide single crystal according to claim 6, comprising: nitrogen as an n-type impurity, wherein a concentration of the n-type impurity by the nitrogen is within a range between 5×10¹⁸ atm/cm³ and 9×10¹⁸ atm/cm³ or more.

10. The silicon carbide single crystal according to claim 6, comprising: aluminum as a p-type impurity, wherein a concentration of the p-type impurity by the aluminum is 1×10¹¹ atm/cm³ or less.
